(19) United States
(12) Patent Application Publication
(10) Pub. No.: US 2014/0177170 A1
(43) Pub. Date: Jun. 26, 2014

(54) Electronic Control Cabinet with Cooling

(71) Applicant: Minimax GmbH & Co. KG, Bad Oldesloe (DE)

(72) Inventor: Hartwig STEFFEN, Reinbek (DE)

(73) Assignee: Minimax GmbH & Co. KG, Bad Oldesloe (DE)

(21) Appl. No.: 14/134,059

(22) Filed: Dec. 19, 2013

(30) Foreign Application Priority Data
Dec. 21, 2012 (EP) 12198984.2

(51) Int. Cl. H05K 7/20

(52) U.S. Cl. CPC H05K 7/20009
USPC 361/692

(57) ABSTRACT

An electronic control cabinet for a fire detection panel and/or extinguishing control panel, including a housing having a fastening structure for modules including a module housing in which an electronic assembly is arranged, the housing having entry and exit openings for an air flow wherein a cooling device for the modules to be cooled includes horizontal first and second ducts between two essentially vertical first and second ducts, the respectively first ducts guiding a cold-air flow to the modules to be cooled and the respectively second ducts leading a warm-air flow away from the modules to be cooled, and the horizontal ducts having openings for the air flow of the cold and warm air at those places where the modules to be cooled are arranged.

### CROSS-REFERENCE TO RELATED APPLICATIONS

This application claims the benefit and priority of European Application No. 12198984.2, filed Dec. 21, 2012. The entire disclosure of the above application is incorporated herein by reference.

### FIELD

The invention relates to an electronic control cabinet for a fire detection panel and/or extinguishing control panel.

### BACKGROUND

The inventive control cabinet can be used wherever a fire detection panel and/or extinguishing control panel exists and the modules that are present in the electronic control cabinet generate heat so that they have to be cooled.

Electronic control cabinets for fire detection panels and/or extinguishing control panels are generally known and consist of a housing having a fastening structure for modules in which electronic assemblies are arranged, the modules being interconnected and connected to an outside area having external components. Modules of this type consist of a housing and the electronic assemblies arranged in the interior.

The electronic assemblies arranged in the modules can contain circuit parts or semiconductor components that generate a thermal power loss that has to be dissipated. To operate the electronic assemblies and their components in the specified temperature range, it may be requisite to cool the modules, i.e. their electronic assemblies, in addition to cooling by free convection as it takes place in the known prior art.

However, free convection can be impeded or stopped by installed internal fittings above and below the modules such a conduits. To increase the performance of individual modules and to dissipate locally a higher thermal power loss, it is not sufficient to utilize free convection.

As a rule, electronic control cabinets in the above-mentioned area of application exhibit modules having ventilation slots in the upper and lower area of their housing close to the plinth. Such module housings are for example designated as Phoenix-ME10.

However, module housings that are similar in terms of function and structure are used.

As a rule, the cable terminals of these modules are remote from the plinth. In the central area of these modules essentially the electronic components are arranged in the housing that generate heat in the case of high power requirements, and hot spots arising in the case of insufficient cooling can even lead to the unsoldering of parts from the electronic assemblies.

Cooling of these modules in the electronic control cabinet is thus requisite.

The prior art discloses various solutions for cooling electronic components in control cabinets.

DE 40 35 213 C2 describes a housing having a cooling device in which electronic assemblies are cooled by a flow of air, to avoid heat from accumulating. What is cooled are plates that are arranged in the housing, below and above the plates feed and discharge channels for the warm and cold air being arranged, the air being fed uniformly to all plates and the cold air being produced by means of a fan.

DE 26 38 118A1 describes a ventilation module for cooling electronic components, where several electronic components are arranged one on top of the other, vertical air ducts serving to feed cold air and to discharge warm air and horizontal air ducts being arranged above and below the plates to be cooled and magazine units, so that each unit to be cooled is supplied with a uniform air jet across the entire surface.

DE 20 2004 006 252 U1 describes a cooling system for appliances and network cabinets that likewise exhibits horizontal and vertical air ducts and a ventilator, electronic module units being cooled and heat exchangers being present.

This prior art reveals vertical and horizontal air ducts in electronic control cabinets for cooling electronic assemblies.

DE 22 11 268A1 discloses an electronic control cabinet for electronic plug-in units, consisting of a housing having a fastening possibility for electronic assemblies, a cooling device being arranged between two vertical ducts, the respective first vertical duct guiding a cold air flow and the respective second vertical duct guiding away a warm air flow. The electronic assemblies to be cooled are not modules that consist of a housing in which electronic assemblies are arranged, the housings having entry and exit openings for an air flow. Horizontal ducts between the two vertical ducts are not present in this control cabinet, only partitions for deflecting the air flow between the vertical ducts.

The electronic assemblies which represent printed circuit boards and plug-in elements on a contact strip that are mounted on a plug-in unit are cooled by an air flow that is deflected at the partition situated above and below, the plug-in unit for the electronic components being completely open towards the top and the bottom, so that electronic components having a particular thermal stress cannot be cooled separately or to a specific degree. The control cabinet does not exhibit a horizontal duct having several openings.

The disadvantage of this pre-known prior art is that all electronic components are cooled uniformly which only makes sense if all modules experience the same degree of warming. In electronic control cabinets, where modules are present on which warming to a varying degree takes place, this has the disadvantage that modules that do not warm up or only exhibit a low degree of warming up are cooled in the same way as modules that exhibit a very high degree of warming up.

Further it cannot be identified that the proposed solutions are suitable for being employed for electronic control cabinets for a fire detection panel and/or extinguishing control panel, since these control cabinets are equipped with modules that exhibit a warming-up that varies greatly and thus also have to be cooled differently.

### SUMMARY

It is therefore the object of the invention to develop an electronic control cabinet for a fire detection panel and/or extinguishing control panel whose modules are cooled in such a way that the heat of each module that is generated is dissipated with the required power at the place where it is generated.

This object is achieved in that there is produced in an electronic control cabinet for a fire detection panel and/or extinguishing control panel a cooling structure that cools only those modules that warm up, to be precise as a function of the heat they generate.

The inventive solution provides an electronic control cabinet for a fire detection panel and/or extinguishing control panel that comprises a housing having a fastening structure for the modules or their housings, electronic assemblies being arranged in the modules. The modules can be interconnected or connected to an outside area having external components.

So that the modules can be fastened at different places of the electronic control cabinet, it is advantageous if they exhibit a quick-action fastening means that can be fastened to the fastening structure of the housing with little effort. For example a top-hat rail from the prior art is known as the fastening means on the housing of the electronic control cabinet.

As the quick-action fastening means on the housing of a module, for example a snap connection on the one side of the housing of the module or in the cabinet is known that is designed using a barb means pivotable counter to a spring force. On the other side of the housing of the module, a latching lug can be arranged that latches into the top-hat rail. Other quick-action fastening means on the housing of the module are conceivable. In this way, the modules can be arranged with little effort inside the electronic control cabinet at a place where the task requires this for which the electronic control cabinet for a fire detection panel and/or extinguishing control panel is used.

The modules comprise a housing that can be made of plastic, in which at least one electronic assembly is arranged, the housing exhibiting entry openings for the supply of an air flow for cooling the electronic assembly. These entry openings are also called housing entry openings for cold air below. The housing furthermore exhibits exit openings for a warm air flow that is formed by the supplied cold air after cooling the at least one electronic assembly. These exit openings are also called housing exit openings for warm air below. These openings are preferably arranged at the top and at the bottom of the housing. The modules can be modules that require intensive or little cooling or no cooling at all.

So that the electrical assemblies of the modules in the electronic control cabinet can be cooled in such a way as is required by their individual warming-up, cold air in the electronic control cabinet has to be guided in a targeted manner to the individual modules. For this purpose, cooling devices for the modules to be cooled have to be arranged in the electronic control cabinet, that essentially consist of vertical and horizontal ducts, i.e. as a rule there is fed on one or on both sides of the electronic control cabinet by a vertical duct a cold air flow that warms up as a result of the cooling and is discharged as a warm air flow on one or the other side in a vertical duct.

In an advantageous design variant, the vertical duct for supplying the cold air flow is situated on the respectively opposite side of the electronic control cabinet, on which the vertical duct for the warm air to be discharged is arranged.

It is advantageous if the cooling apparatus exhibits at least one ventilator. This ventilator can be arranged inside or also outside the electronic control cabinet.

It is furthermore advantageous if the cooling apparatus exhibits at least one heat exchanger in which the warm air for reuse or heat recovery is cooled.

The cold air that is fed in the vertical air duct is guided into the modules to be cooled in one or more essentially horizontal first ducts, there being situated in the first horizontal duct openings for the cold air that is leaving (exit openings for cold air). The essentially horizontal first ducts for the supply of the cold air are arranged below the module to be cooled or the modules to be cooled of a row of modules. Above each row of modules, an essentially horizontal second duct is arranged in which openings for the warm air that is entering are situated (entry openings for warm air). These openings for cold air that is leaving and for the warm air that is entering are situated at the those points where the modules to be cooled are arranged.

Here it is advantageous if the exit openings for cold air are situated in the horizontal duct that feeds cold air, opposite the housing entry openings for cold air of the housing of the modules to be cooled, and in a similar manner the entry openings for warm air are situated in the horizontal duct that discharges warm air, opposite the housing exit openings for warm air of the housing of the modules to be cooled. This can be carried out such that the modules with their openings are fastened to the fastening possibility in the housing of the electronic control cabinet, opposite the openings in the horizontal duct. The size of the vertical distance between the openings in the horizontal duct and the modules can vary, i.e. both openings can lie directly opposite or be interconnected by an air-guidance coupling. The openings can be round, angular, oval, and other suitable openings.

In an advantageous design of the invention, the horizontal duct above the modules for the warm air and the horizontal duct, situated there above, below the modules for the cold air can also be designed as a duct having a partition.

To increase the efficiency of the cooling for the modules that receive a more intensive cooling, in a further advantageous embodiment, air-guidance couplings are arranged between the modules and the horizontal first and second ducts.

The air-guidance coupling is a device for guiding cold or warm air. It guides the cold or warm air flow from the openings of the horizontal ducts to the modules and/or their housings with as little loss as possible and represent the connection in terms of air flow between the horizontal ducts and the modules to be cooled.

The air-guidance coupling can exhibit various embodiments—rigid, flexible. At the ends, adapter fittings for snapping on or latching into the entry and exit openings can be provided on the modules and the openings on the horizontal ducts.

The air-guidance couplings can be provided in a semi-round, round, oval, angular, rectangular and U-shape and in any other suitable shape.

As a result of the apparatus, the air flow takes the following path. At the lower end of the vertical duct, the cold air flow enters into the apparatus, flows upwards and passes into the or one of the horizontal ducts that is or are situated below the housing of the modules. Openings in these horizontal ducts for the cold air that is leaving are situated opposite the modules to be cooled. The cold air that is leaving the horizontal ducts through these openings now enters through entry openings on the housing of the module to be cooled. As a result of these entry openings on the housings of the modules, the cold air flow is guided, with or without air-guidance coupling, into the housing of the modules that warm up, they being cooled in the process. The warm air flow that is generated in this way leaves the housings of the modules through the exit openings on the housing of the module and passes, with or without air-guidance coupling, through the openings of the essentially horizontal second duct. The warm air flow passes through the essentially horizontal second duct into the vertical duct for warm air, is guided upwards by it and can now leave the apparatus.

Modules that contain electronic assemblies with a lower thermal power loss and which therefore warm up to a lesser degree require no intensive and direct air through flow. It is sufficient, to provide for these modules only openings for warm and cold air above and below the module in the horizontal duct for warm and cold air.

Modules having only very little power or that are operated only very rarely, require no cooling so that no openings in the horizontal duct for warm and cold air have to be provided for positions in the electronic control cabinet where these modules are arranged.

The positions of the closable openings in the horizontal duct for warm and cold air can be marked at the respective places in the horizontal duct and broken out after it has been installed. It is furthermore advantageous to close them again as required by suitable means and means known from the prior art. For this purpose, for example suitable flaps or plugs or other solutions known according to the prior art can be provided in the horizontal duct.

So that the modules can communicate with external components, there are arranged on the one side of the modules terminals for the outside area on the modules. The external components that conceivable are fire detectors of the most varying types and connection technology and limit-value and loop detectors, various types of actuators such as sounders, flashing beacons, valves or relays and also fire brigade peripherals and further interconnected control panels. As a rule, these terminals are located on the opposite side of the fastening possibility of the module. So that cables can be routed to the side of the module, it is advantageous to arrange a cable duct on or in front of the horizontal duct, in which the cables are routed to these modules. At its upper and its lower side, this cable duct can exhibit a slot through which the cables with their terminals can be routed towards the outside and can be plugged into the corresponding modules from above or from below by means of a plug.

The inventive solution provides for several rows of modules to be arranged on top or below each other, a plurality of essentially horizontal ducts for warm and cold air having to be provided above and below the modules.

Of course the solution is also suitable for arranging a plurality of rows of modules next to each other, a plurality of vertical ducts for warm and cold air then having to be arranged on both sides of the modules.

An advantage of the electronic control cabinet is that the modules are cooled with the requisite power and at that place in the electronic control cabinet where the heat is generated. Here it is advantageous that in the case of changes in the control cabinet, as they can occur when repositioning the modules or also by expanding by adding further modules, it is also the supply of cold air and the discharge of warm air that can be changed with little effort.

It is furthermore advantageous that the heat energy that has been discharged can be utilized by means of heat exchangers.

### DRAWINGS

The invention is explained in more detail below using an exemplary embodiment and four figures. In the drawings:

FIG. 1 shows the schematic illustration of an electronic control cabinet in section B-B of FIG. 2,

FIG. 2 shows a schematic illustration of an electronic control cabinet in section A-A of FIG. 1,

FIG. 3 shows a module having cooling openings in the central area, and

FIG. 4 shows a top view of the module in FIG. 3.

### DETAILED DESCRIPTION

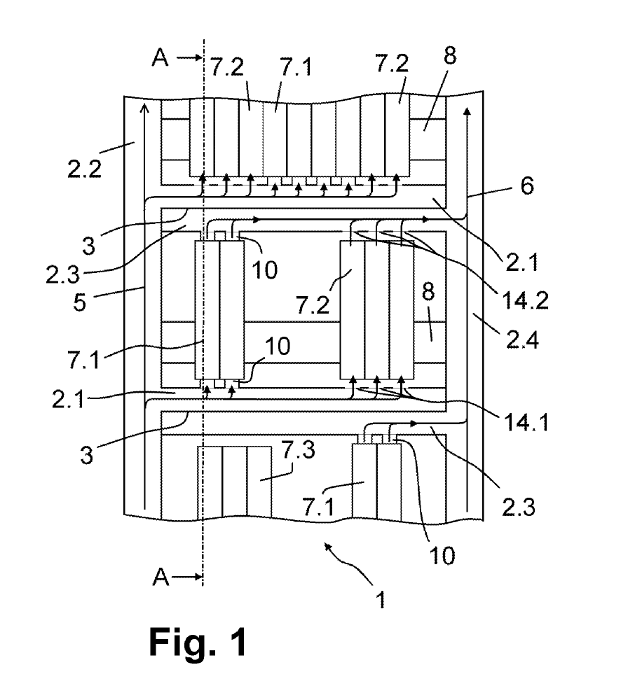

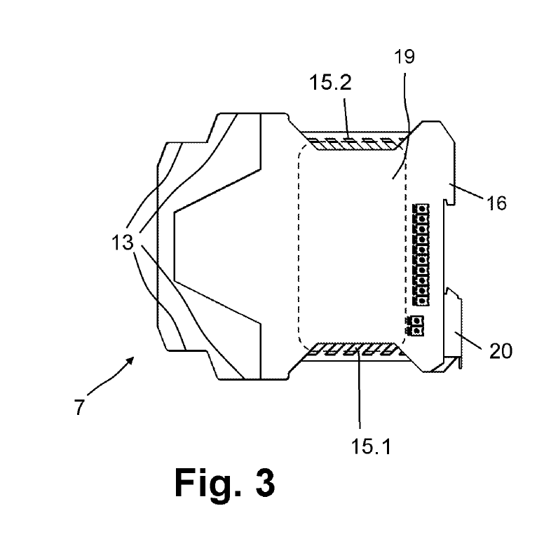

FIG. 1 shows a schematic illustration an electronic control cabinet 1 in which different modules 7.1, 7.2, 7.3 are arranged. These are modules 7 having a housing of that type as it is shown as an example in FIG. 3. The modules can be arranged as modules 7.1 with intensive cooling, as module 7.2 with low cooling and/or as module 7.3 without any cooling. With their housings, the modules 7.1, 7.2, 7.3 are releasably arranged on a fastening structure, a top-hat rail 8 and can be interconnected. The releasable arrangement of the modules 7.1, 7.2, 7.3 on the top-hat rail 8 makes it possible, in the case of a changed task, to arrange the modules 7.1, 7.2, 7.3 differently in the electronic control cabinet 1 or to install them additionally. According to this different arrangement, it is also the cooling in the electronic control cabinet that can be changed with little effort. To cool the modules 7.1, 7.2, vertical and horizontal ducts 2.1, 2.2, 2.3, 2.4 are arranged in which an air flow with cold air 5 is fed through a vertical duct 2.2 and an air flow with warm air 6 is discharged via a vertical duct 2.4.

Between the horizontal ducts 2.1, 2.3 a partition 3 for separating the air flow of warm air 6 and cold air 5 is arranged.

The air flow 5, 6 takes the following path through the apparatus. At the lower end of the left vertical duct 2.2, the cold air flow 5 enters into the apparatus, flows upward and passes into the horizontal ducts 2.1 that are arranged in a plurality of levels and that are situated below the housings of the modules 7.1, 7.2 of the module rows. The cold air flow 5 is guided, with or without air-guidance coupling 10, to the housings of the modules 7.1, 7.2, through openings 14.1 for the exit of air in the horizontal ducts 2.1 for cold air, via the entry openings 15.1 on the housing of the modules (not shown in FIG. 1) into the housings of the modules 7.1, 7.2 that heat up, they being cooled in the process. The warm air flow 6 generated in this manner leaves the housings of the modules 7.1, 7.2 through the exit openings 15.2 on the housing of the modules (not shown in FIG. 1) and passes, with or without air-guidance coupling 10, through the opening 14.2 for the entry of air into the horizontal duct 2.3 for the warm air. The warm air flow 6 passes through the horizontal duct 2.3 towards the right into the vertical duct 2.4 for warm air and flows upward through it and can then leave the apparatus.

The modules 7.1 that require intensive cooling are connected by means of forced cooling to the horizontal ducts 2.1 and 2.3; i.e., between the horizontal ducts 2.1 and 2.3 and the housing of the module 7.1, air-guidance couplings 10 are arranged between the openings 14.1 for the exit of air in the horizontal duct 2.1 and the entry openings 15.1 on the module housing, through which the air flow of the cold air 5 is fed to the module 7.1 with intensive cooling, and through the air-guidance couplings 10 between the openings 14.2 for the entry of air in the horizontal duct 2.3 and the exit openings 15.2 on the module housing, the air flow of the warm air 6 is returned from the module 7.1 with intensive cooling to the horizontal duct 2.3. By means of this duct 2.3, the air flow of warm air 6 is then guided from the module 7.1 to the vertical duct for warm air 2.4 that then represents the collection duct for warm air.

For modules 7.2 with little cooling, the air-guidance couplings 10 are not requisite, but only the openings 14.1, 14.2 for the exit of air and for the entry of air from the and into the horizontal ducts 2.1, 2.3. These openings 14.1, 14.2 can be closed in case the modules 7.2 are arranged at a different place and cooling is no longer requisite at the intended place.

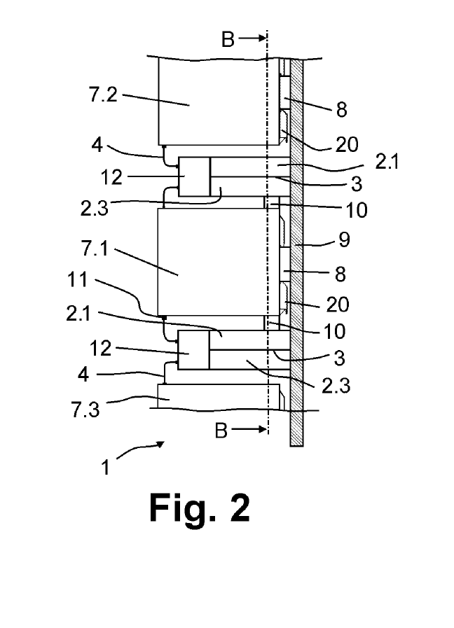

How the section of FIG. 1 is carried out, can be gathered from FIG. 2.

FIG. 2 shows in a schematic illustration an electronic control cabinet 1 in section A-A of FIG. 1. This illustration further reveals how the top-hat rails 8 are arranged on the installation plate 9 of the electronic control cabinet 1. FIG. 2 also reveals that in front of the horizontal cooling ducts 2.1, 2.3 with the partition 3, the cable duct 12 is arranged from which cables 4 lead that are fastened, by means of the clamp 11, in the front part of the respective housing of the module 7.1, 7.2, 7.3.

FIG. 3 shows an embodiment of a housing for the module 7, where exit and entry openings 15.1, 15.2 are arranged at the top and at the bottom and through which the air flow of the cold and the warm air 5, 6 can flow so as to cool the electronic assembly of the module 7 inside the housing, which assembly is situated in the central area 19 of the module 7 in the housing (not illustrated). According to the intensity of the load, this electronic assembly represents the heat-generating zone that has to be cooled. On one side of the housing of the module 7, the snap connection 20 and the latching lug 16 by means of which lug the housing of the module 7 is releasably fastened to the top-hat rail 8, are arranged. The other side exhibits a terminal 13 for the cable 4 on the housing of the module 7.

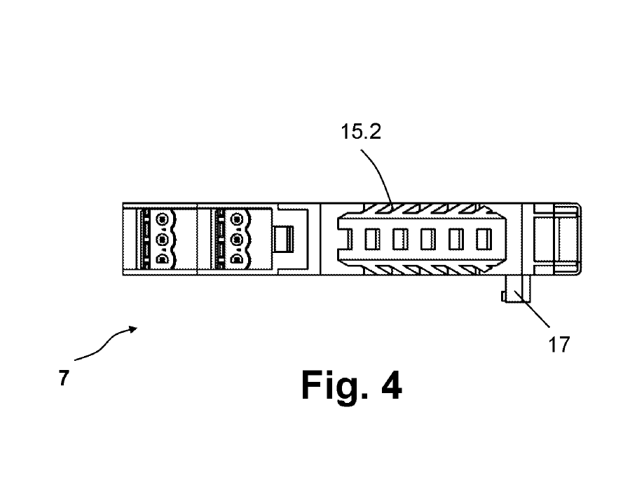

FIG. 4 shows the housing of the module in a top view with the exit opening 15.2 and the plug 17 by means of which the module 7 can be connected to the respectively next module 7 and a continuous module row, as illustrated in FIG. 1, can be formed.

### LIST OF THE REFERENCE SYMBOLS THAT ARE USED

1 electronic control cabinet
2.1 horizontal cold-air duct
2.2 vertical cold-air duct
2.3 horizontal warm-air duct
2.4 vertical warm-air duct
3 partition
4 cable
5 cold-air flow
6 warm-air flow
7 module
7.1 module with intensive cooling
7.2 module with little cooling
7.3 module without cooling
8 top-hat rail
9 mounting plate
10 air-guidance coupling
11 cable clamp
12 cable duct
13 terminal for cable on the module
14.1 opening in 2.1 for air leaving (exit openings for cold air)
14.2 opening in 2.3 for air entering (entry openings for warm air)
15.1 entry openings on the housing of module 7 for cold air
15.2 exit opening on the housing of module 7 for warm air
16 latching lug on the housing of the module
17 plug on the housing of the module for connection to the neighboring module
19 central area having the heat-producing zone
20 snap-on connection opposite the latching lug on the housing of module 7

1. An electronic control cabinet (1) for a fire detection panel and/or extinguishing control panel, including a housing having a fastening structure for modules including a module housing in which an electronic assembly is arranged, the module housing having entry and exit openings (15.1, 15.2) for an air flow (5, 6), comprising:
a cooling device for the modules (7, 7.1, 7.2) to be cooled having an essentially horizontal first and second ducts (2.1, 2.3) between two essentially vertical first and second ducts (2.2, 2.4),
the respectively first duct (2.1, 2.2) guiding a cold-air flow (5) to the modules (7, 7.1, 7.2) to be cooled and the respectively second duct (2.3, 2.4) leading a warm-air flow (6) away from the modules (7, 7.1, 7.2) to be cooled, and
the horizontal ducts (2.1, 2.3) having openings (14.1, 14.2) for the airflow of the cold and warm air (5, 6) at those places where the modules (7, 7.1, 7.2) to be cooled are arranged.

2. The apparatus according to claim 1, wherein the horizontal ducts (2.1, 2.3) represent a duct having a partition (3).

3. The apparatus according to claim 1, wherein the cooling apparatus exhibits at least one ventilator.

4. The apparatus according to claim 1, wherein the cooling apparatus exhibits at least one heat exchanger.

5. The apparatus according to claim 1, wherein the openings (14.1, 14.2) exhibit apparatus for closing.

6. The apparatus according to claim 1, wherein between the openings (14.1, 14.2) and the modules (7.1), devices for guiding cold or warm air (5, 6) are arranged.

7. The apparatus according to claim 6, wherein the devices between the modules (7.1) and the openings (14.1, 14.2) represent air-guidance couplings (10) in one of a round, semi-round, oval, angular, rectangular or U-shape.

8. The apparatus according to claim 1, wherein a cable duct (12) is arranged on or on top of the horizontal air duct.

9. The apparatus according to claim 8, wherein the horizontal cable duct (12) is arranged in front of the horizontal air duct and a cable (4) leads from the cable duct (12) into the front part of the module (7, 7.1,7.2, 7.3).

10. The apparatus according to claim 1, wherein the modules (7) represent modules (7.1) that require intensive cooling, and modules (7.2, 7.3) that require little cooling or no cooling at all.
